(19) United States
(12) Patent Application Publication
(10) Pub. No.: US 2021/0135080 A1
(43) Pub. Date: May 6, 2021

(54) THERMOELECTRIC DEVICE

(71) Applicant: City University of Hong Kong, Kowloon (HK)

(72) Inventors: Vaithinathan Karthikeyan, Kowloon Tong (HK); A. L. Roy Vellaisamy, Kowloon (HK); Chung-Kai Joseph Wong, Kowloon (HK)

(21) Appl. No.: 16/668,174

(22) Filed: Oct. 30, 2019

(51) Int. Cl. H01L 35/32; H01L 35/04; H01L 35/16

(52) U.S. Cl. CPC H01L 35/32; H01L 35/16; H01L 35/04

(57) ABSTRACT

A system and a method for a thermoelectric device for generating electricity including a flexible substrate, at least one n type semiconductor element positioned on the substrate, at least one p type semiconductor element positioned on the substrate, the at least one n type semiconductor element and the at least one p type semiconductor element are arranged adjacent or in contact with each other on the flexible substrate, a first electrode and a second electrode positioned on the flexible substrate, wherein the at least one n type semiconductor element and the at least one p type semiconductor element defining a conductive path to the first and second electrode for electrons to flow, and; wherein the thermoelectric device generating an electrical power output in response to heat or a temperature gradient applied to the device.

### TECHNICAL FIELD

The present disclosure relates to a thermoelectric device that converts heat to electricity.

### BACKGROUND

Wearable devices e.g. fitness trackers, smartwatches, are becoming increasingly popular with consumers. Wearable devices require portable power sources such as example batteries. Portable power sources often can suffer from power output capacity for a small footprint. A small portable power source often has a limited output capacity, while large portable power sources have a large enough power output but can be very heavy and are less suitable for wearable devices. Portable power sources can often be fragile and are limited by their size.

Additionally common power sources for wearable devices are batteries e.g. Lithium ion batteries or other rechargeable batteries. Accidents related to batteries and battery systems can occur reasonably frequently. For example, Lithium ion batteries are easily prone to explosions at high temperatures or due to physical damage. Several current portable power sources also require constant recharging. There is a need for an improved power source.

### SUMMARY OF THE INVENTION

The present disclosure relates to a thermoelectric device that converts applied heat i.e. thermal energy to electricity. In particular, the present disclosure relates to a wearable thermoelectric device that can be worn by a user and generates electricity when exposed to body heat i.e. a temperature difference caused by body heat. The thermoelectric device described herein induces a voltage and a current flow when exposed to a heat source.

The present disclosure further relates to a thermoelectric device that can be used as a wearable power source to power wearable electronic devices. The thermoelectric device as described herein can be worn such that the thermoelectric device coverts body heat to electricity, which allows the device to function as a wearable power source. The thermoelectric device disclosed herein can also function as a touch sensor to sense a touch from a person.

According to a first aspect the present disclosure relates to a thermoelectric device for generating electricity, the thermoelectric device comprising:

a flexible substrate,

at least one n type semiconductor element positioned on the substrate,

at least one p type semiconductor element positioned on the substrate,

the at least one n type semiconductor element and the at least one p type semiconductor element are arranged adjacent or in contact with each other on the flexible substrate, a first electrode and a second electrode positioned on the flexible substrate,

wherein the at least one n type semiconductor element and the at least one p type semiconductor element defining a conductive path to the first and second electrode for electrons to flow, and;

wherein the thermoelectric device generating an electrical power output in response to heat or a temperature gradient applied to the device.

In one configuration the thermoelectric device comprises at least one conductor member positioned on the flexible substrate, the at least one p type semiconductor element and the at least one n type semiconductor element positioned adjacent each other and spaced from each other, and wherein the at least one conductor connecting each adjacent n type semiconductor element with an adjacent p type semiconductor element to define a path to conduct the generated electrical power output.

In one configuration flexible substrate is bendable and comprises a flexural modulus value such that the flexible substrate can bend or be wrapped around about a limb of a human body while maintaining structural integrity.

In one configuration the flexible substrate comprises Polyimide or Polyethylene Terephthalate (PET), Polycarbonate, Polypropylene, Polyethylene, Polyvinyl chloride (PVC).

In one configuration the first electrode and the second electrode being coupled to either of the semiconductor elements or the conductor member.

In one configuration the n type semiconductor element, the p type semiconductor element generating a flow of electric current in response to heat or temperature gradient applied to the device and the electric current flowing through the conductor member.

In one configuration the p type semiconductor element comprises Tin Telluride (SnTe) or Bismuth Antimony Telluride (Bi_{0.5}Sb_{1.5}Te₃) , and the n type semiconductor element comprises Lead Telluride (PbTe) or Bismuth Telluride(Bi₂Te₃).

In one configuration the n type semiconductor element and the p type semiconductor element are elongate legs, each leg comprises a longitudinal axis that is longer than a transverse axis of the leg.

In one configuration the n type semiconductor leg and the p type semiconductor leg being arranged adjacent and parallel to each other.

In one configuration conductor member comprises a metal that defines a current path for the current generated the semiconductor elements due to an applied heat or an applied temperature gradient.

In one configuration the flexible substrate comprises a flexible sheet comprising a flexural modulus value such that the flexible substrate can bend about a limb of a human body while maintaining structural integrity.

In one configuration the conductor member comprises aluminium or copper.

In one configuration the conductor member comprises an aluminium or copper foil as output contact.

In one configuration the p type semiconductor element and the n type semiconductor element comprise a thin film having a thickness between 50 nm to 150 nm, and preferably 100 nm.

In one configuration the conductor member comprises a thin foil having a thickness of 25 nm to 75 nm, and preferably 50 nm.

In one configuration the thermoelectric device comprises a plurality of p type semiconductor elements and a plurality of n type semiconductor elements, the semiconductor elements arranged in an alternating layout on the flexible substrate, such that one p type semiconductor element is located adjacent one n type semiconductor element in the alternating arrangement.

In one configuration the thermoelectric device comprises a plurality of conductor members, wherein a p type semiconductor element is coupled to an adjacent n type semiconductor arrangement by a conductor member.

In one configuration each p type and n type semiconductor element is coupled to two conductor members, wherein each end of the semiconductor element is coupled to a separate conductor member.

In one configuration the thermoelectric device comprises N number semiconductor elements (sum of p type semiconductor elements and n type semiconductor elements) and;

comprises between N−1 to N+1 number of conductor, and a pair of electrodes.

In one configuration each of the first electrode and second electrode are located at opposing ends of the flexible substrate with the semiconductor elements are arranged in parallel array on a face of the flexible substrate, wherein the semiconductor elements and conductor members defining a series electrical path for the generated current to flow through.

In one configuration the semiconductor elements and the conductor members are disposed in an in-plane layout on a first face of the flexible substrate, and wherein the first face is opposite to a second face of the flexible substrate to which heat is applied.

In one configuration the thermoelectric device functions as a wearable thermoelectric generator that is configured to generate a current in response to the device being exposed to body heat or a temperature gradient from body heat, and wherein the wearable thermoelectric generator functions as a wearable power source.

In one configuration the thermoelectric device comprises a first flexible substrate and a second flexible substrate, the first flexible substrate supporting the p type semiconductor element and the second flexible substrate supporting the n type semiconductor element, and

wherein the thermoelectric device comprising a sandwich structure of the first flexible substrate, the p type semiconductor element, the n type semiconductor element and the second flexible substrate.

In one configuration the p type semiconductor element is connected to and directly contacts a portion of the n type semiconductor element, the n type semiconductor element and p type semiconductor element being connected at a sensing junction to sense an application heat or an application of a temperature gradient to the device.

In one configuration the first electrode is disposed on the first substrate and the second electrode is disposed on the second substrate.

In one configuration the p type semiconductor element overlaps a portion of the n type semiconductor element in region where the p type semiconductor element contacts and is attached to the n type semiconductor element (the sensing junction).

In one configuration heat applied to the first substrate and/or the second substrate causes a pulse of electrical current to be generated due to an applied heat or a temperature gradient, and wherein the amplitude of the pulse of electrical current being related to the magnitude of the applied heat or applied temperature heat gradient.

In one configuration the thermoelectric device as described is configured to function as a touch sensor that is configured to detect a touch from a user by detecting the heat from the touch and generating a current in response.

According to a second aspect the present disclosure relates to a thermoelectric device that converts heat to electrical power, the thermoelectric device comprising:

a flexible substrate;

a plurality of thermoelectric modules disposed on the flexible substrate,

a first electrode and a second electrode disposed on the flexible substrate, and;

wherein the plurality of thermoelectric modules electrically coupled to each other and at least one thermoelectric module in electrical communication with the first electrode and at least one thermoelectric module in electrical communication with the second electrode, the plurality of thermoelectric modules defining a conductive path between the first electrode and the second electrode, and;

wherein each thermoelectric module generating an electrical current and voltage when exposed to heat or a temperature gradient.

In one configuration each thermoelectric module generates a voltage when exposed to heat or a temperature gradient.

In one configuration each thermoelectric module comprises a p type semiconductor element and a n type semiconductor positioned adjacent each other and separated from each other, wherein each of the semiconductor elements are disposed on the flexible substrate.

In one configuration the thermoelectric modules are arranged adjacent each other on the flexible substrate such that the semiconductor elements are positioned in an alternating layout, wherein a p type semiconductor element is followed by a n type semiconductor element.

In one configuration the thermoelectric device comprises a plurality of conductor members disposed on the flexible substrate, wherein the conductor members providing intra module connections and inter module connections.

In one configuration the intra module connections comprise a conductor member interconnecting the p type semiconductor element and n type semiconductor element defining the thermoelectric module.

In one configuration the inter module connections comprise a conductor member interconnecting adjacent thermoelectric modules together, wherein a p type semiconductor element of a first thermoelectric module is connected to a n type semiconductor element of a second thermoelectric module adjacent the first thermoelectric module.

In one configuration each p type semiconductor element and the n type semiconductor element are coupled to each other by a conductor member.

In one configuration plurality of thermoelectric modules and the conductor members are positioned on the flexible substrate to form an undulating pattern of p type semiconductor elements, n type semiconductor elements and conductor members.

In one configuration the thermoelectric modules are electrically coupled to each other via the conductor members, the conductor members defining an electrical path for the generated electrical current to travel to at least one of the electrodes.

In one configuration the thermoelectric modules are electrically coupled to each other in series connection or a parallel connection.

In one configuration the thermoelectric device comprises four thermoelectric modules and a plurality of conductor members, the conductor members connecting adjacent thermoelectric modules to each other and conductor members interconnecting the semiconductor elements of each thermoelectric module to each other and the thermoelectric modules and conductor elements are arranged in a series electrical connection with each other.

In one configuration flexible substrate is bendable and comprises a flexural modulus value such that the flexible substrate can bend or be wrapped around about a limb of a human body while maintaining structural integrity.

In one configuration the flexible substrate comprises Polyimide or Polyethylene Terephthalate (PET), Polycarbonate, Polypropylene, Polyethylene, Polyvinyl chloride(PVC).

In one configuration the n type semiconductor element, the p type semiconductor element generating a flow of electric current in response to heat or temperature gradient applied to the device and the electric current flowing through the conductor member.

In one configuration the p type semiconductor element comprises Tin Telluride (SnTe) or Bismuth Antimony Telluride (Bi_{0.5}Sb_{1.5}Te₃) , and the n type semiconductor element comprises Lead Telluride (PbTe) or Bismuth Telluride(Bi₂Te₃).

In one configuration the thermoelectric device comprises three rows of thermoelectric modules and conductor members disposed on the substrate and each row comprising four thermoelectric modules coupled to each other by conductor members.

In one configuration the thermoelectric device as described functions as a flexible power source that converts residual heat or waste heat to electrical power or current and voltage.

In one configuration the thermoelectric device as described functions as a wearable power source that converts body heat to electrical power or current and voltage.

According to a third aspect the present disclosure relates to a thermoelectric device comprising:

a multilayer structure, the multilayer structure comprising a first flexible substrate defining a first layer,

a second flexible substrate defining a second layer,

a thermoelectric module sandwiched between the first flexible substrate and the second flexible substrate, the thermoelectric module defining a third layer,

a first electrode disposed on the first substrate,

a second electrode disposed on the second substrate,

wherein the thermoelectric module is configured to generate an electric current and electric voltage when the thermoelectric module is exposed to a heat or a temperature gradient.

In one configuration thermoelectric module comprises a p type semiconductor element and a n type semiconductor element.

In one configuration the p type semiconductor element and the n type semiconductor element are each a flexible sheet, the p type semiconductor sheet is attached to the first flexible substrate and the n type semiconductor sheet is attached to the second flexible substrate.

In one configuration each flexible substrate is bendable and comprises a flexural modulus value such that the flexible substrate can bend or be wrapped around about a limb of a human body while maintaining structural integrity.

In one configuration each flexible substrate comprises Polyimide or Polyethylene Terephthalate (PET), Polycarbonate, Polypropylene, Polyethylene, Polyvinyl chloride(PVC).

In one configuration the p type semiconductor element comprises Tin Telluride (SnTe) or Bismuth Antimony Telluride (Bi_{0.5}Sb_{1.5}Te₃), and the n type semiconductor element comprises Lead Telluride (PbTe) or Bismuth Telluride(Bi₂Te₃).

In one configuration the p type semiconductor sheet is attached to a portion of the n type semiconductor sheet, the attached portion defining a contact region.

In one configuration a sensing junction is defined at the contact region.

In one configuration the thermoelectric module is configured to sense heat at the sensing junction and generate an electric current and voltage when heat is sensed at the sensing junction by the Seebeck effect.

In one configuration the thermoelectric device is used as a contact sensor or a touch sensor to sense a touch by detecting heat from a person touching the sensor, the heat being detected at the sensing junction and the device generating an electrical current in response to sensing the touch.

According to a fourth aspect the present disclosure relates to a method of forming a thermoelectric power source, the thermoelectric power source configuration to generate a current and/or voltage in response to heat, the method comprising the steps of:

providing a flexible substrate,

disposing a plurality of n type semiconductor elements on the flexible substrate, wherein disposing comprises a deposition of the n type semiconductor elements on the substrate,

disposing a plurality of p type semiconductor elements on the flexible substrate adjacent the n type semiconductor elements,

wherein the disposing comprising deposition of the p type semiconductor elements on the substrate,

depositing a plurality of metal conductor members in positions to interconnect the n type semiconductor elements with the adjacent p type semiconductor elements,

positioning a first electrode and a second electrode on the substrate, and wherein the thermoelectric power source is configured to generate an electric current and voltage when exposed to heat or a temperature gradient.

In one configuration the step of disposing the n type and p type semiconductor elements comprising deposition of the p type and n type semiconductor elements respectively by using thermal evaporation.

In one configuration the p type semiconductor element comprises Tin Telluride (SnTe) or Bismuth Antimony Telluride (Bi_{0.5}Sb_{1.5}Te₃) , and the n type semiconductor element comprises Lead Telluride (PbTe) or Bismuth Telluride(Bi₂Te₃).

In one configuration the flexible substrate comprises flexible substrate is bendable and comprises a flexural modulus value such that the flexible substrate can bend or be wrapped around about a limb of a human body while maintaining structural integrity, and the flexible substrate comprises Polyimide or Polyethylene Terephthalate (PET), Polycarbonate, Polypropylene, Polyethylene, Polyvinyl chloride(PVC).

In one configuration the method comprises the additional step of applying an encapsulation layer around the device to encapsulate the device.

According to a fourth aspect the present disclosure relates to a method of forming a thermoelectric sensor, the method comprising the steps of:

providing a first flexible substrate,

providing a second flexible substrate,

depositing a p type semiconductor element on the first flexible substrate, wherein the p type semiconductor element comprises a flexible sheet,

depositing a n type semiconductor element on the second substrate, wherein the n type semiconductor element comprises a flexible sheet,

attaching the p type semiconductor element to a portion of the n type semiconductor element to define a sensing junction,

wherein the thermoelectric sensor is configured to detect heat at the sensing junction and generate an electric current and voltage in response to the detected heat.

In one configuration the p type semiconductor element comprises Tin Telluride (SnTe) or Bismuth Antimony Telluride (Bi_{0.5}Sb_{1.5}Te₃) , and the n type semiconductor element comprises Lead Telluride (PbTe) or Bismuth Telluride(Bi₂Te₃).

In one configuration the flexible substrate comprises flexible substrate is bendable and comprises a flexural modulus value such that the flexible substrate can bend or be wrapped around about a limb of a human body while maintaining structural integrity, and the flexible substrate comprises Polyimide or Polyethylene Terephthalate (PET), Polycarbonate, Polypropylene, Polyethylene, Polyvinyl chloride(PVC).

In one configuration the method comprises the additional step of applying an encapsulation layer around the device to encapsulate the device.

Features from one or more embodiments or configurations described herein may be combined with features of one or more other embodiments or configurations. Additionally, more than one described embodiment or configuration or form may be used together during a process of respiratory support of a patient.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7) and, therefore, all sub-ranges of all ranges expressly disclosed herein are hereby expressly disclosed. These are only examples of what is specifically intended and all possible combinations of numerical values between the lowest value and the highest value enumerated are to be considered to be expressly stated in this application in a similar manner.

It should be understood that alternative embodiments or configurations may comprise any or all combinations of two or more of the parts, elements or features illustrated, described or referred to in this specification.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

As used herein the term ‘and/or’ means ‘and’ or ‘or’, or where the context allows both.

In the following description like numbers denote like features.

As used herein “(s)” following a noun means the plural and/or singular forms of the noun.

In this specification, the word “comprising” and its variations, such as “comprises”, has its usual meaning in accordance with International patent practice. That is, the word does not preclude additional or unrecited elements, substances or method steps, in addition to those specifically recited. Thus, the described apparatus, substance or method may have other elements, substances or steps in various embodiments. The term “comprising” (and its grammatical variations) as used herein are used in the inclusive sense of “having” or “including” and not in the sense of “consisting only of”.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount.

### BRIEF DESCRIPTION OF THE DRAWINGS

Notwithstanding any other forms which may fall within the scope of the present disclosure, one or more embodiments of a thermoelectric generator will now be described, by way of example only, with reference to the accompanying drawings in which:

FIG. 1A illustrates a top view of an example configuration of a thermoelectric device that can be used as a wearable power source.

FIG. 1B illustrates a perspective view of the thermoelectric device of FIG. 1A.

FIG. 2A illustrates a top view of a further example configuration of a thermoelectric device that can be used as a power source.

FIG. 2B illustrates a perspective view of the thermoelectric device of FIG. 2A.

FIG. 3A illustrates a flow chart for forming the thermoelectric device shown in FIG. 1A, 1B or FIG. 2A, 2B.

FIG. 3B illustrates a schematic diagram of the steps for forming the thermoelectric device of FIG. 1A, 1B.

FIG. 4 illustrates a test set up of the thermoelectric device of FIG. 1A, 1B wrapped around an arm of a person and coupled to a multimeter to test operation of the device.

FIG. 5A illustrates a test set up of the thermoelectric device of FIG. 1A, 1B wrapped around an arm of a person and coupled to a wrist watch to test if the device can power a wrist watch.

FIG. 5B illustrates an infrared image of the thermoelectric device of FIG. 1A, 1B on the forearm of the user.

FIG. 6A illustrates the thermoelectric device of FIG. 2A, 2B disposed on a pipe and coupled to a multimeter to test operation of the device.

FIG. 6B illustrates an infrared image of the thermoelectric device of FIG. 2A, 2B disposed on a pipe.

FIG. 7 illustrates a further configuration of thermoelectric device that can be used as a touch sensor.

FIG. 8A shows a plot of electrical pulses detected in response to a series of touches detected on the thermoelectric device of FIG. 7.

FIG. 8B illustrates a plot of a single pulse from the plot of FIG. 8A.

FIG. 8C illustrates a graph of the sensor responsivity of the thermoelectric device of FIG. 7.

FIG. 9 illustrates a method of forming a thermoelectric device of FIG. 7.

### DETAILED DESCRIPTION

The foregoing describes only a preferred embodiment of the present invention and modifications, obvious to those skilled in the art, can be made thereto without departing from the scope of the present invention. While the invention has been described with reference to a number of preferred embodiments it should be appreciated that the invention can be embodied in many other forms.

The present disclosure relates to a thermoelectric device that converts heat i.e. thermal energy to electricity. Expressed another way the thermoelectric device generates electricity i.e. an electrical current when the thermoelectric device is exposed to a temperature gradient i.e. temperature difference. In particular, the present disclosure relates to a wearable thermoelectric device that can be worn by a user. The thermoelectric device described herein generates an electric current and due to an induced voltage when exposed to a heat source e.g. body heat.

The thermoelectric device described herein is a solid state device that generates electricity when exposed to heat, in particular when exposed to a heat flux or a temperature difference. The thermoelectric device comprises a semiconductor materials and utilises the Seebeck effect i.e. a thermoelectric effect to convert heat flux (i.e. temperature differences) directly into electricity i.e. a current and voltage. Current flows when the thermoelectric device is exposed to heat i.e. a heat flux due to the Seebeck effect. Expressed another way a temperature gradient across the thermoelectric device causes a voltage i.e. potential difference, which in turn causes a current to flow. This phenomenon is due to the Seebeck effect.

The term heat refers to thermal energy applied to the thermoelectric device. The term heat also refers to a temperature difference created from the region where the heat is applied to an opposing region. The heat is applied to a portion of the semiconductor elements in the thermoelectric device.

In one example embodiment the thermoelectric device comprises: a flexible substrate, at least one n type semiconductor element positioned on the substrate, at least one p type semiconductor element positioned on the substrate, the at least one n type semiconductor element and the at least one p type semiconductor element are arranged adjacent or in contact with each other on the flexible substrate, a first electrode and a second electrode positioned on the flexible substrate, wherein the at least one n type semiconductor element and the at least one p type semiconductor element defining a conductive path to the first and second electrode for electrons to flow, and; wherein the thermoelectric device generating an electrical current in response to heat applied to the device. The applied heat causes a temperature difference across the device. The temperature difference across the p type semiconductor element and the n type semiconductor element causes charge to flow within the semiconductor elements. The flow of charge is an electrical current, and the electrical current generated may be output as electrical power output for powering an electrical load connected to the thermoelectric device.

In one configuration the thermoelectric device comprises at least one conductor member positioned on the flexible substrate, the at least one p type semiconductor element and the at least one n type semiconductor element positioned adjacent each other and spaced from each other, and wherein the at least one conductor connecting each adjacent n type semiconductor element with an adjacent p type semiconductor element to define a path to conduct the generated electrical current in the semiconductor elements. The p type semiconductor element and n type semiconductor element are appropriately doped to create a p type and n type semiconductor element. In the p type semiconductor element the primary charge carriers are holes i.e. a movement of positive charges. In the n type semiconductor element the primary charge carriers are electrons i.e. movement of electrons. The charges e.g. electrons move from the hot portion to the cold portion of the semiconductor elements i.e. away from the heat source or along the descending temperature gradient. There is a charge build up in the semiconductor elements at one end. The conductor member which may be a metal e.g. copper or gold or aluminium conducts charge away from the semiconductor elements.

In this configuration the flexible substrate is bendable and comprises a flexural modulus value such that the flexible substrate can bend or be wrapped around about a limb of a human body while maintaining structural integrity. In one example the flexible substrate comprises Polyimide or Polyethylene Terephthalate (PET), Polycarbonate, Polypropylene, Polyethylene, Polyvinyl chloride(PVC). In one example the p type semiconductor element comprises Tin Telluride (SnTe) or Bismuth Antimony Telluride (Bi_{0.5}Sb_{1.5}Te₃), and the n type semiconductor element comprises Lead Telluride (PbTe) or Bismuth Telluride(Bi₂Te₃). The first electrode and the second electrode being coupled to either of the semiconductor elements or the conductor member. The n type semiconductor element, the p type semiconductor element generates a flow of electric current in response to heat i.e. temperature gradient applied to the device and the electric current flowing through the conductor member.

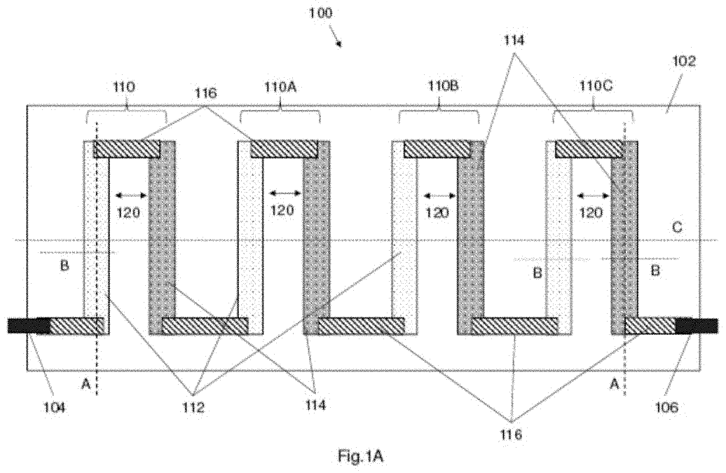

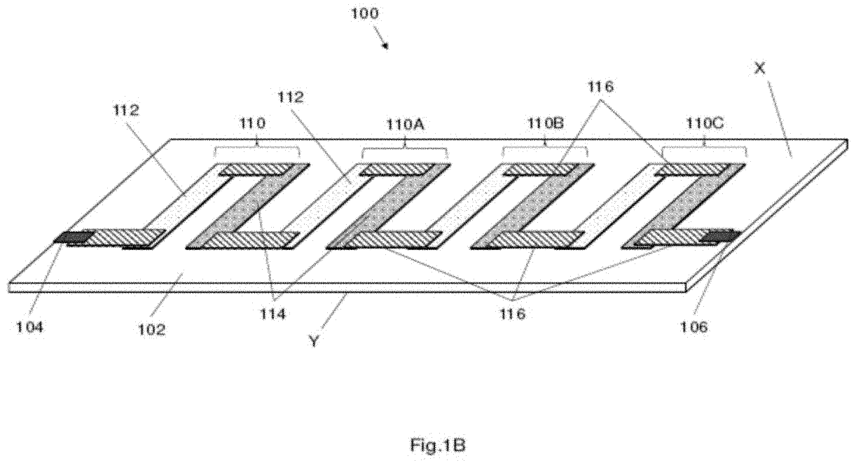

FIG. 1A shows a top view of an example configuration of a thermoelectric device 100. FIG. 1B shows a perspective view of the thermoelectric device 100. The thermoelectric device 100 comprises a flexible substrate 102. A plurality thermoelectric modules 110, a first electrode 104 and a second electrode 106 are disposed on the flexible substrate 102. The thermoelectric device 100 generates electricity i.e. an electrical current when exposed to heat applied to the thermoelectric device 100. Explained another way the thermoelectric device 100 generates an electrical current in response to a temperature gradient. Each thermoelectric module generates electricity when exposed to heat.

The flexible substrate is bendable and comprises a flexural modulus value such that the flexible substrate can bend or be wrapped around about a limb of a human body while maintaining structural integrity. The flexible substrate 102 is flexible and bendable such that it can be wrapped around a curved surface. The flexible substrate 102 does not permanently deform i.e. plastically deform when it is bent or twisted e.g. wrapped around an arm of a user or wrapped a portion of a user's body. The flexible substrate 102 further does not crack or break when bent. In one example the flexible substrate 102 comprises polyimide. In one example the flexible substrate 102 comprises a flexible polyimide sheet. As shown in FIG. 1A the flexible substrate 102 is a sheet. The flexible substrate 102 is a rectangular shaped sheet, as shown in FIG. 1. The flexible substrate 102 is quite thin to allow it to be flexible. The flexible substrate 102 comprises a thickness between 250 micrometres to 750 micrometres. In one example construction the thickness of the flexible substrate is 500 micrometres.

The polyimide material of the flexible substrate 102 is advantageous because of its high temperature stability. Further polyimide has a flexural modulus and a Youngs modulus that allows the substrate to bend and flex about curved surfaces. In alternative configurations the flexible substrate 102 may comprise Polyethylene Terephthalate (PET), Polycarbonate, Polypropylene, Polyethylene, Polyvinyl chloride(PVC). These materials may be formed into a flexible sheet that has a flexural modulus that is low enough to allow the sheet to bend or be wrapped about a curved surface. The flexible substrate is advantageous because it can be flexed and bent.

Referring again to FIG. 1A, the thermoelectric device comprises a plurality of thermoelectric modules 110, 110a, 110b, 110C (110-110C). The plurality of thermoelectric modules 110-110C are arranged adjacent each other in a series arrangement on the flexible substrate 102. Each thermoelectric module 110 comprises a p type semiconductor element 112 and a n type semiconductor element 114, all positioned on the flexible substrate 102. Each thermoelectric module generates an electric current i.e. electricity when exposed to heat. The temperature difference created due to the application of heat to the thermoelectric device causes an electric current to be generated by way of the Seebeck effect. The p type semiconductor element and the n type semiconductor element are positioned adjacent each other or in contact with each other. The thermoelectric device 100 comprises a plurality of conductor members 116. Each p type semiconductor element 112 and n type semiconductor element 114 are coupled together by the conductor member 116. Each of the semiconductor elements within each thermoelectric module are interconnected to each other by conductor members 116. The conductor member 116 provides a conductive path for the current to be transported away from the semiconductor elements 112, 114. P type semiconductor elements are numbered as 112 and n type semiconductor elements are numbered as 114.

As shown in FIG. 1A and FIG. 1B, each thermoelectric module 110 comprises a p type semiconductor element 112 and an n type semiconductor element 114 arranged adjacent each other and spaced from each other by a gap 120. The p ty pe semiconductor element 112 and the n type semiconductor element 114 are positioned parallel to each other. The conductor member 116 extends across the gap 120 and connects the p type semiconductor element 112 and the n type semiconductor element 114.

The p type semiconductor element 112 and the n type semiconductor element 114 are elongate legs i.e. elongate members. Each leg comprises a longitudinal axis A that is longer than a transverse axis B of the leg. The legs 112, 114 are positioned on the flexible substrate sheet 102 in a manner that the longitudinal axis A of each leg 112, 114 is arranged substantially perpendicular to the longitudinal axis C of the flexible substrate 102 sheet, as shown in FIG. 1A.

The semiconductor elements 112, 114 are formed from a thermoelectric material i.e. a material that responds to eat or a temperature gradient. A thermoelectric material is formed from a semiconductor material, in which, charges move i.e. a current is caused due to a heat i.e. due to a temperature gradient. The p type semiconductor element 112 comprises a semiconductor that is doped to be a p type semiconductor i.e. a semiconductor where the main charge carriers are holes.

In the illustrated example of FIGS. 1A and 1B, the p type semiconductor elements are 112 comprise Tin Telluride (SnTe). Alternatively, the p type semiconductor element may comprise Bismuth Antimony Telluride (Bi_{0.5}Sb_{1.5}Te₃). In the illustrated example of FIGS. 1A and 1B, the n type semiconductor element comprises Lead Telluride (PbTe). Alternatively, the n type semiconductor elements may comprise Bismuth Telluride(Bi₂Te₃). Preferably the p type semiconductor elements are identical in size, shape and material across the multiple thermoelectric modules. Preferably the n type semiconductor elements are identical in size, shape and material between the multiple thermoelectric modules.

The p type semiconductor element 112 and n type semiconductor element 114, of each thermoelectric module comprise a thin film having a thickness between 50 nm to 150 nm. Preferably the p type semiconductor element 112 and n type semiconductor element 114 comprise a thickness of 100 nm.

The conductor member 116 is positioned perpendicular to the semiconductor elements 112, 114. A longitudinal axis of each conductor member 116 is substantially perpendicular to the longitudinal axis A of each semiconductor element i.e. leg 112, 114. The conductor members 116 are formed from a metal or another suitable electric conductor. For example, each conductor member 116 comprises aluminium or copper foil and it operates as an output contact. Each conductor member is a metal foil having a thickness between 25 nm to 75 nm. Preferably the thickness of the metal foil of the conductor member 116 is 50 nm.

Referring again to FIG. 1A, the thermoelectric device 100 comprises a plurality of thermoelectric modules 110 positioned adjacent each other on the substrate 102. In the illustrated example of FIG. 1A, the thermoelectric device 100 comprises four thermoelectric modules 110, 110A, 110B, 110C electrically coupled to each other. Each thermoelectric module is electrically coupled to an adjacent thermoelectric module by a conductor member 116. As shown in FIG. 1A and 1B, thermoelectric module 110 is coupled to thermoelectric module 110A by a conductor member 116. As seen in FIG. 1A, adjacent thermoelectric modules 110-110C are interconnected by conductor members 116. The conductor members 116 provide intra module connections (i.e. connecting the p and n type element of each thermoelectric module together) and inter module connection (i.e. connecting adjacent thermoelectric modules together). The interconnections define a conductive path for electrical current to travel through. The conductor members 116 interconnect adjacent semiconductor elements.

The thermoelectric modules 110-110C are interconnected to form a series electrical connection i.e. a series arrangement. The conductor members 116 define a conductive path for the generated current to flow. The first electrode 104 and second electrode 106 are positioned at opposing ends of the flexible substrate 102. The first electrode 104 and the second electrode 106 are connected to the conductor members 116. An electrical path i.e. a conductive path is defined between the first electrode 104 and the second electrode 106 via the thermoelectric modules 110-110C.

As shown in the example configuration of FIG. 1A, the thermoelectric device 100 comprises a plurality of p type and n type semiconductor elements (i.e. a plurality of thermoelectric modules positioned adjacent each other, wherein each thermoelectric module comprises at least a p type semiconductor element and a n type semiconductor element). The p type semiconductor elements 112 and n type semiconductor elements 114 are arranged in an alternating layout on the flexible substrate 102, such that one p type semiconductor element is located adjacent a n type semiconductor element in the alternating arrangement. Similarly, the thermoelectric device 100 comprises a plurality of conductor members, wherein adjacent p type semiconductor elements and n type semiconductor elements are coupled together by a conductor element i.e. a p type semiconductor element is coupled to an adjacent n type semiconductor element by a conductor member.

Each p type semiconductor element 112 and each n type semiconductor element 114 is coupled to two conductor members 116, wherein each end of each semiconductor element is coupled to a separate conductor member. As seen in FIGS. 1A and 1B, each semiconductor element is coupled to a conductor member at each end of the semiconductor element. The conductor members extend in opposing direction from a single semiconductor element. In the illustrated configuration the thermoelectric device 100 comprises N number of semiconductor elements in total (i.e. the sum of p type semiconductor elements 112 and n type semiconductor elements 114) and the device 100 comprises N+1 conductor members. In the illustrated example of FIG. 1A and 1B, the device 100 comprises 8 semiconductor elements. The device 100 comprises 4 thermoelectric modules. The device 100 comprises 9 conductor elements.

Alternatively, the thermoelectric device may comprise between N−1 to N+1 conductor elements. In one alternative form the device may comprise N−1 conductor elements. In a further alternative form the thermoelectric device may comprise N conductor elements. The first electrode 104 and second electrode 106 are each positioned in contact with a conductor member 116. The electrodes are positioned at opposing ends of the substrate 102.

As shown in FIG. 1A, the thermoelectric modules 110 are arranged in an in-plane layout i.e. the semiconductor elements 112, 114 are arranged in an in-plane layout on the flexible substrate 102. Each of the semiconductor legs 112, 114 are positioned on a first face, face X. Face X is a flat face and is parallel to a horizontal plane that extends across the face X. The thermoelectric modules 110 are positioned on the face X i.e. the semiconductor elements 112, 114 are positioned flat on the face X. The first face (face X) is a user facing side and is an opposing face to a second face (face Y). In use, heat is applied to the second face (face Y). Face Y is in contact with a heat source e.g. face Y is in contact with a limb of a user. In-plane layout means the semiconductor elements and conductor elements are positioned such that they form a substantially planar layout on the face X of the substrate 102.

The semiconductor elements 112, 114 are arranged in a parallel array on a face of the flexible substrate 102. The semiconductor elements 112, 114 are interconnected by the conductor members 116. As shown in FIG. 1A, the semiconductor elements 112, 114 and the conductor members 116 are positioned on the substrate 102 to form an undulating pattern along the substrate 102. In the illustrate example in FIG. 1A, the semiconductor elements (i.e. the thermoelectric modules) and the conductor members are positioned to form repeating U shaped patterns on the substrate 102. The first electrode 104 and the second electrode 106 can be connected to wires to transmit current away from the thermoelectric device 100. The current generated by the thermoelectric modules 110-110C is conducted through the thermoelectric modules, conductor members 116 to the first and second electrode. A load can be connected to the first and second electrodes 104, 106 to receive the current and power the load.

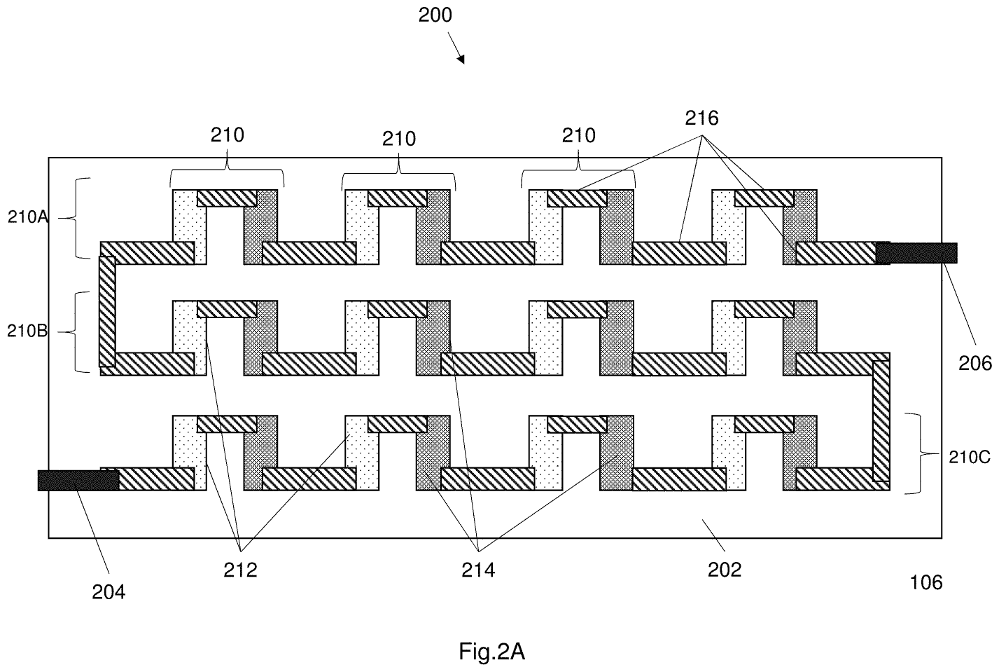

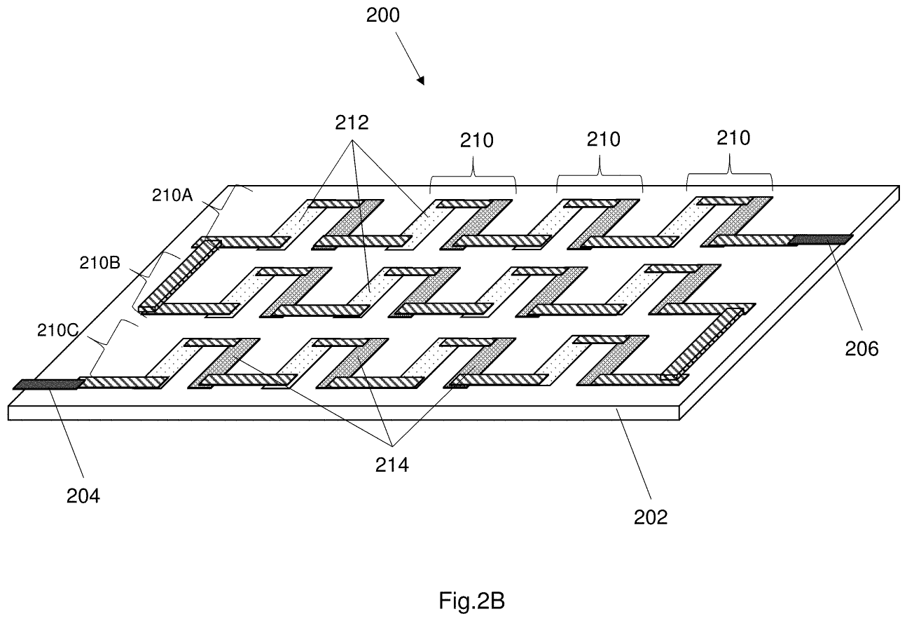

FIGS. 2A and 2B show a second configuration of a thermoelectric device 200. FIG. 2A shows a top view and FIG. 2B shows a perspective view. The thermoelectric device 200 functions to generate electricity in response to being exposed to heat or a temperature gradient. The thermoelectric device 200 of FIGS. 2A and 2B is similar in construction to the thermoelectric device 100 shown in FIGS. 1A and 1B. The thermoelectric device 200 comprises an array of thermoelectric modules. As shown in FIGS. 2A and 2B, the thermoelectric device 200 comprises multiple rows of thermoelectric modules disposed on a flexible substrate 202. The flexible substrate is a sheet of flexible material. The flexible substrate 202 may, in one example construction be a polyimide sheet. Alternatively, the substrate may be formed from any other suitable material similar to substrate 102.

The thermoelectric modules in the device illustrated in FIG. 2A, may be similar in construction to the thermoelectric modules 210 described in reference to FIG. 1. Each thermoelectric module comprises a p type semiconductor element 212 and a n type semiconductor element 214 positioned adjacent or in contact with each other. In the illustrated example the semiconductor elements 212, 214 are positioned adjacent each other and spaced from each other. The device 200 comprises conductor members 216 connecting adjacent semiconductor elements. Adjacent thermoelectric modules 210 are interconnected to each other by conductor members 216. The p type semiconductor elements 212 and n type semiconductor elements 214 comprise similar materials as the semiconductor elements described earlier with reference to FIG. 1. For example, the p type semiconductor elements 212 comprise Tin Telluride (SnTe) and the n type semiconductor elements comprises Lead Telluride (PbTe).

The device 200 comprises three rows of thermoelectric modules 210A, 210B, 210C. The thermoelectric modules 210 within each row are connected in a series electrical connection i.e. a series arrangement. Each row may be in electrical communication with the adjacent rows. In one example form, the rows 210A, 210B, 210C may be interconnected to each other in a series electrical connection. In another example form, the rows 210A-210C may be connected in a parallel electrical connection. The thermoelectric device 200 comprises at least a pair of electrodes (i.e. a first electrode 204 and second electrode 206) that are in electrical communication with the rows of thermoelectric modules 210A-210C.The device 200 may also comprise multiple bridging conductors (i.e. conductor members) 220 that electrically couple the rows 210A-210C with each other to form either a series or parallel arrangement. In the illustrated example the bridging conductors 220 connect the rows of thermoelectric modules in a series electrical arrangement.

The rows of adjacent, interconnected thermoelectric modules are arranged such that the longitudinal axis or each row is parallel with the other rows. The plurality of semiconductor elements are arranged in rows of interconnected semiconductor elements. As shown in FIG. 2A and 2B, there are three parallel rows of interconnected semiconductor elements. The rows are interconnected by conductor elements.

Optionally either of the thermoelectric devices 100 and 200 may comprise an encapsulation layer (not illustrated). The encapsulation layer may be disposed over the thermoelectric modules (i.e. over the semiconductor elements and conductor members). The encapsulation layer may encapsulate the device 100 or device 200. In one example the encapsulation layer may comprise a thin layer of polyimide that surrounds the substrate, the thermoelectric modules, electrodes and bridging members. The encapsulation layer provides protection to the devices 100 and 200 from environmental damage.

The thermoelectric devices 100 and 200 as described herein are wearable devices. The thermoelectric devices 100 and 200 are used as a wearable power source to power other wearable electronic devices. The thermoelectric devices 100 and 200 function as thermoelectric generators having a high current density and power density. The thermoelectric devices 100 and 200 generate an electrical current when the devices are worn. The devices 100 and 200 harness i.e. harvest body heat and generate electricity when exposed to body heat. A user contacting face (i.e. face Y) of the substrate gets heated by body heat when the device 100 or 200 is wrapped around a limb of a user. For example the device 100 or 200 may be wrapped around an arm of the user. One face of the substrate is heated by the user's body heat. This creates a temperature difference across the device 100, 200. This heat (i.e. temperature difference) causes a movement of charge. The devices 100, 200 convert heat to electricity i.e. the heat causes a current flow. The current flow can be used to power another wearable device. The in-plane arrangement of the semiconductor elements in the thermoelectric devices 100, 200 in order to absorb as much body heat as possible. The in-plane arrangement of the thermoelectric modules (i.e. the semiconductor elements) helps to increase the exposure area of the thermoelectric modules i.e. the area of the thermoelectric modules that are exposed to body heat. An increased area of exposure results in a larger current or voltage being produced by the thermoelectric device 100, 200.

The wearable power generator (i.e. thermoelectric devices 100, 200) are advantageous because the device is a flexible, wearable power generator. The power generator (i.e. thermoelectric device 100, 200) generates power i.e. an electric current by harvesting body heat. The thermoelectric device 100, 200 as described herein provides a small portable power source that does not include chemicals like batteries, thereby making the thermoelectric device 100, 200 inherently safer. The device 100, 200 is also less prone to explosions due to physical damage or high temperatures. The wearable power generator (thermoelectric device 100, 200) provides a flexible device that can be wrapped about structures e.g. a user's limbs without breaking or cracking, unlike traditional thermoelectric generators that utilise rigid ceramic plates.

The thermoelectric device 100, 200 is advantageous because high temperatures generate a greater current and power. The thermoelectric device 100, 200 as described herein is also of a simple construction. The thermoelectric device 100, 200 as described herein utilises a flexible substrate and is flexible enough to conform to a user's limbs. The thermoelectric device 100, 200 is also robust due to the flexible substrate and the in-plane construction. The semiconductor elements and conductor members comprise a thin film construction thereby making the device more robust and provides a device with a small footprint. The device 100, 200 also provides a thin wearable power source.

The thermoelectric device 100, 200 is also advantageous because the thermoelectric generator 100, 200 power output capacity is not limited. The device 100, 200 is advantageous because the devices continuously harvests waste heat. The thermoelectric device 100, 200 as described provides a flexible, potable and wearable device that generates electrical current and electrical power. The device 100, 200 provides a longer lifespan than batteries because the device simply harvests body heat rather than generating power due to chemical processes.

The described thermoelectric device 100, 200 functions as a wearable thermoelectric generator to generate electricity i.e.

a current when exposed to body heat or a temperature gradient from body heat. The device 100, 200 is advantageous because it provides a wearable and flexible thin film thermoelectric device (i.e. a thermoelectric generator) that extracts power efficiently from a low grade heat e.g. body heat. The device 100, 200 as described is made of a flexible substrate which allows the device to be worn on a limb of the user. Alternatively the thermoelectric device 100, 200 as described can be used to harvest low grade heat from other heat sources e.g. a pipe, a thermal exchanger etc. The thermoelectric device 100, 200 is flexible and therefore can be wrapped around curved surfaces to extract heat and generate electricity.

The thermoelectric device 100, 200 can be constructed to any suitable dimensions. Some example applications of the thermoelectric device 100, 200 will now be described. The thermoelectric device 100 can be used as a wearable power source due to its smaller footprint than the device 200. The wearable power source can continuously generate power (i.e. electrical power) from body heat or any other low grade heat source. The device 100 can be formed small enough to be used as a portable and wearable power source. The device comprises a flexible substrate which allows the device 100 to be manipulated and bent and flexed into desired configurations when worn. The device 100 is advantageous because it continuously generates electrical power as long as it is exposed to heat. Unlike a battery, there is no finite capacity due to chemicals. The device 100 will generate power as long there is body heat.

The device 100, 200 may also be integrated into electronic gadgets such as for example a human exoskeleton. The thermoelectric device 100, 200 can be easily integrated into an electronic gadget. Thermoelectric device 200 can also function as a flexible thermoelectric generator for large scale energy harvesting in industries e.g. harvesting heat from pipes to generate electricity i.e. electric power.

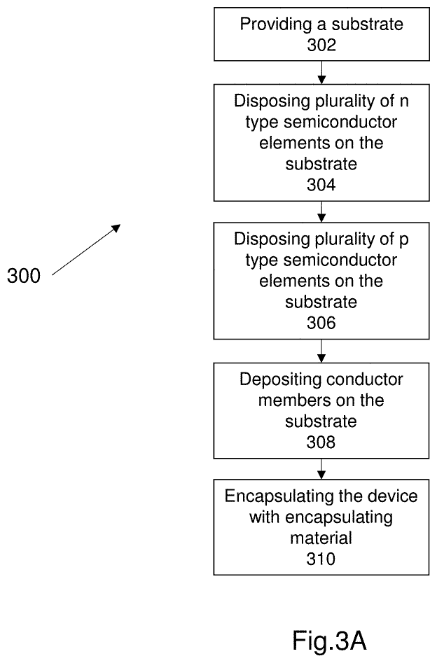

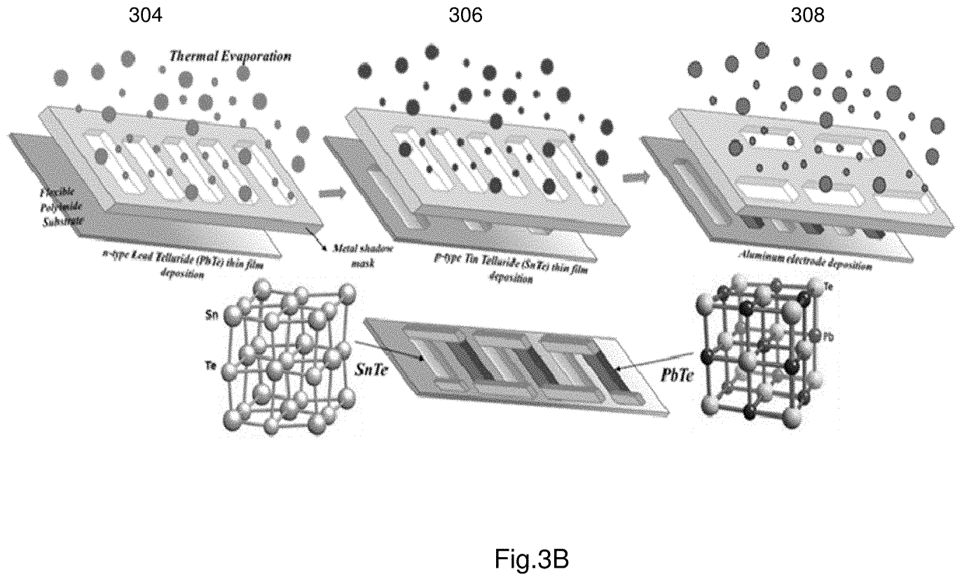

FIG. 3A shows a flow chart of a method 300 of fabricating a thermoelectric device 100, 200 as shown in FIGS. 1A, 1B and FIGS. 2A, 2B. FIG. 3B shows a schematic diagram of the steps to fabricate the thermoelectric device 100, 200. The method 300 is an example method of fabricating a thermoelectric device 100, 200 as described herein that is used as a wearable power source. The method 300 of fabricating a thermoelectric device comprises a plurality of steps. The method 300 commences at step 302. Step 302 comprises provides providing a clean, flexible substrate. The substrate may be polyimide sheet. Step 304 comprises disposing a plurality of n type semiconductor elements onto the substrate. The n type semiconductor elements comprise Lead Telluride (PbTe).

Step 306 comprises disposing a plurality of p type semiconductor elements onto the substrate. The p type semiconductor elements comprise Tin Telluride (SnTe). The semiconductor elements are disposed on the substrate by a process of deposition by thermal evaporation of high purity (e.g. 99.99%) PbTe and SnTe respectively. The deposition is performed at a working pressure of approx. 5×10⁻⁶ mBar and a deposition rate of approximately 10 A/s for the SnTe and 15 A/s for the PbTe. The dimensions and shape of each of the semiconductor elements are achieved by using a metal shadow mask over the substrate. As shown in FIG. 3B steps 304 and 306 utilise a metal shadow mask over the substrate to achieve the desired shape of the semiconductor elements. The metal shadow mask includes openings that are shaped as rectangular legs i.e. rectangular members such that the semiconductor elements form a corresponding shape on the substrate 102. The thickness of the openings in the mask is 500 micrometres such that the semiconductor elements are 500 micrometres. As shown in FIG. 3B, three n type semiconductor elements are deposited onto the substrate and three p type semiconductor elements are deposited onto the substrate.

Step 308 comprises depositing conductor members (including bridging conductor members). The conductor members are aluminium foil. As shown in FIG. 3B, multiple aluminium foils are deposited using a further shadow mask. The mask includes openings such that the conductor members are deposited perpendicular to the semiconductor elements. The conductor members i.e. the aluminium foils are 50 nm thick. FIG. 3B further shows an example molecular structure of each of the p type semiconductor elements (SnTe) and n type semiconductor elements (PbTe). Optionally the method can comprise step 310. Optional step 310 comprises encapsulating device 100, 200 with an encapsulating material.

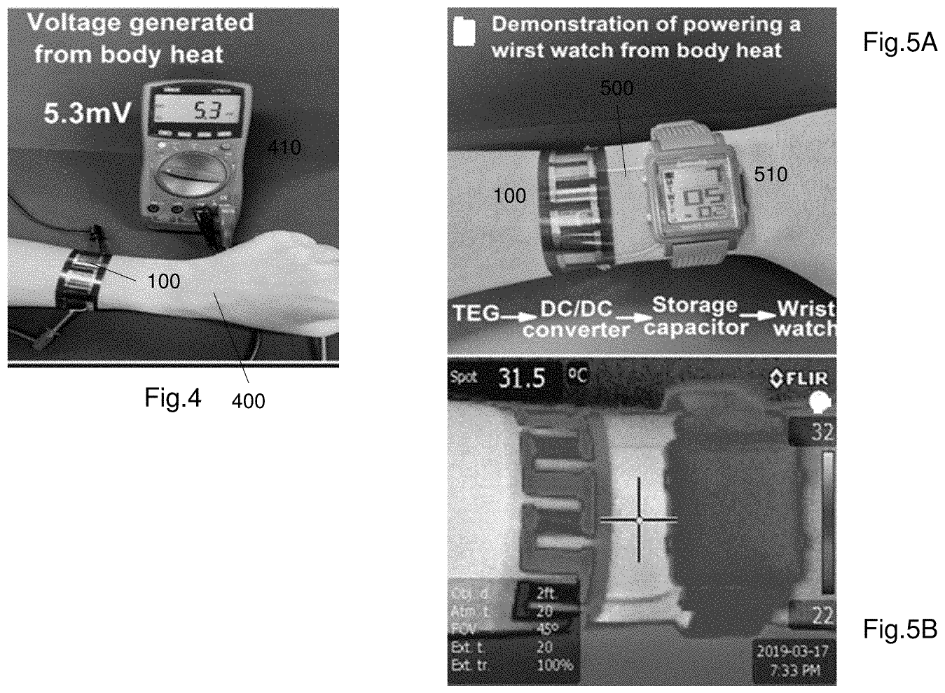

FIGS. 4 to 6B illustrate various testing setups and thermal images illustrating the use of a thermoelectric device 100. FIG. 4 shows the thermoelectric device 100 wrapped around the forearm 400 of a user. The thermoelectric device 100 is connected to a multimeter 410. The probes of the multimeter are connected to the electrodes on the thermoelectric device 100. As seen in FIG. 4 the thermoelectric device 100 generates a voltage of 5.3 mV based on the body heat applied to the device 100. The thermoelectric device 100 converts body heat to electricity and generates a voltage. A current flow is induced due to the voltage.

FIG. 5A illustrates a second testing setup. As shown in FIG. 5A illustrates the thermoelectric device 100 powering a wrist watch from the body heat of the user. The thermoelectric device 100 is wrapped about the forearm 500 of the user, adjacent the wrist 510. The thermoelectric device 100 is connected to a DC/DC converter, which is coupled to a storage capacitor, which is coupled to the wrist watch. The DC/DC converter and storage capacitor are not visible but the schematic is indicated in FIG. 5A. As shown in FIG. 5A the wrist watch is powered and is functioning thereby illustrating the thermoelectric device 100 successfully functions as a power source by harvesting body heat. FIG. 5B illustrates an infrared image of the thermoelectric device 100 on the forearm of the user. The forearm heat, heating a user contacting side of the device 100 which creates a temperature difference across the device 100 and the thermoelectric modules.

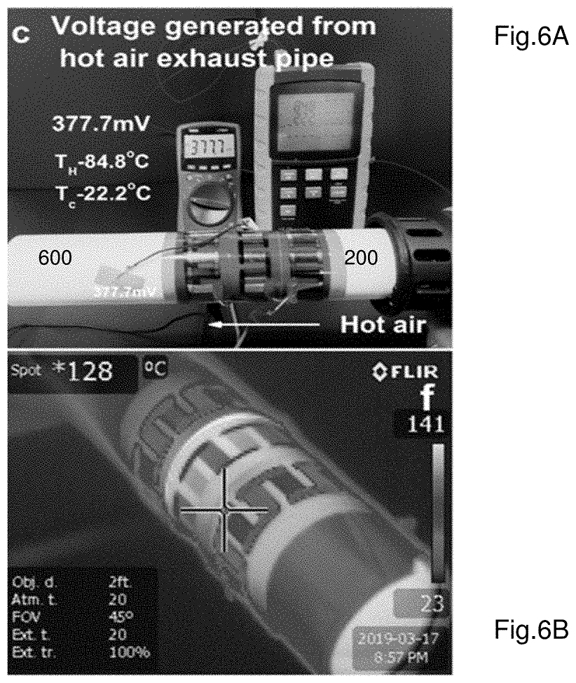

FIG. 6A illustrates the thermoelectric device 200 disposed on a pipe and harvesting heat from the pipe to generate electricity. The thermoelectric device 200 has more thermoelectric modules (i.e. more semiconductor elements), than the construction of device 100. The thermoelectric device 200 can be used for high temperature power harvesting and for generating greater electricity. The device 200 is wrapped about an exhaust pipe 600. The thermoelectric device 200 generated 377.7 mV as measured by a multimeter in the test conducted. FIG. 6A illustrates the device 200 generates a voltage and current by harvesting heat from the pipe 600. The device 200 is stable in the presence of large temperatures e.g. the device can be exposed to 84.8 degrees Celsius. FIG. 6B illustrates an infrared image the thermoelectric device 200 wrapped about an exhaust pipe. The pipe surface that contacts a face of the device 200 is the hottest. The heat from the pipe is harvested and converted to a current and a voltage by the thermoelectric device 200. The illustrated construction of the thermoelectric device 100 is fabricated to have a maximum output voltage of 250 mV and a power density of 8.4 mW/cm², at a temperature difference of 120 degrees Celsius. The thermoelectric device 200 may also be constructed to have similar efficiency and performance.

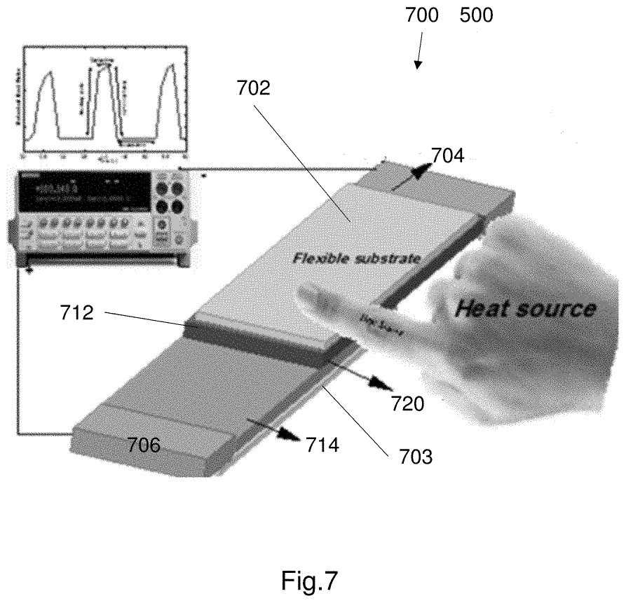

FIG. 7 shows a further configuration of a thermoelectric device 700. The thermoelectric device 700 comprises a flexible substrate 702 and a thermoelectric module 710. The thermoelectric module 710 comprises a p type semiconductor element 712 and a n type semiconductor element 714. The device 700 further comprises a first electrode 704 and a second electrode 706. The first electrode is positioned at an opposing end of the substrate 702 to the end where the second electrode is located.

The flexible substrate 702 is a flexible sheet of polyimide. As shown in the illustrated configuration of FIG. 7, the device 700 comprises a first flexible substrate 702 and a second flexible substrate 703. The first substrate 702 supports the p type semiconductor element 712. The second substrate 703 supports the n type semiconductor element 714. The first and second flexible substrates may be identical to each other in material, size and shape. Each flexible substrate 702, 703 is a rectangular sheet of polyimide material. Alternatively, the first and second substrate may comprise comprises Polyimide or Polyethylene Terephthalate (PET), Polycarbonate, Polypropylene, Polyethylene, Polyvinyl chloride(PVC). Each substrate may be flexible such that it can be bent or wrapped around a pipe.

The p type semiconductor element 712 is a planar member disposed on the first substrate 702. In the illustrated form p type semiconductor element 712 is attached to an inner surface of the first substrate 702. The p type semiconductor element 712 is in the form of a flexible planar film or a flexible planar sheet disposed on the substrate 702. The n type semiconductor element 714 is a planar member disposed on the second substrate 703. In the illustrated form the n type semiconductor element 714 is attached on an inner surface of the second substrate 703. The n type semiconductor element 714 is in the form of a flexible planar film or a flexible planar sheet disposed on the second substrate 703.

In the illustrated configuration the p type semiconductor element comprises Tin Telluride (SnTe). Alternatively, the p type semiconductor element comprises Bismuth Antimony Telluride (Bi_{0.5}Sb_{1.5}Te₃). In the illustrated configuration the n type semiconductor element comprises Lead Telluride (PbTe). Alternatively, the n type semiconductor element comprises Bismuth Telluride(Bi₂Te₃). The first electrode 704 and the second electrode 706 comprise copper or aluminium contacts. The electrodes 704, 706 are preferably thin film electrodes. The substrates, semiconductor elements and the electrodes are preferably formed of a thin film in order to create a device having a small footprint.

The thermoelectric device 700 comprises a sandwich structure comprising a plurality of layers. The layers comprise the first substrate 702, p type semiconductor element 712, n type semiconductor element 714 and the second substrate 704. The thermoelectric module 710 generates electricity when exposed to heat or a temperature difference due to the Seebeck effect. The Seebeck effect results in charge movement in the p type and n type semiconductor elements 712, 714 and results in an induced voltage. The induced voltage causes current to flow. A portion of the p type semiconductor element 712 is attached to a portion of the n type semiconductor element 714. The p type semiconductor element overlaps a portion of the n type semiconductor element in a region where the p type semiconductor element contacts and is attached to the n type semiconductor element.

The thermoelectric device 700 functions as a touch sensor. The sensing region functions as a thermoelectric module since it comprises a p type semiconductor element adjacent a n type semiconductor element. The thermoelectric device 700 is configured to detect a touch from a person by detecting body heat from the touch and generating an electrical current in response. The region where the p type semiconductor contacts and overlaps the n type semiconductor device defines a sensing junction i.e. a sensing region 720. A finger touch is detected by the touch sensor 700 by detecting and measuring a change in voltage and current induced by the heat from the person's finger. The heat transfer between the finger and the sensor surface creates a temperature gradient on the material interface that leads to the generation of an impulse current i.e. a current pulse. A unique current pulse is generated each time the sensor 700 is touched by a user's finger.

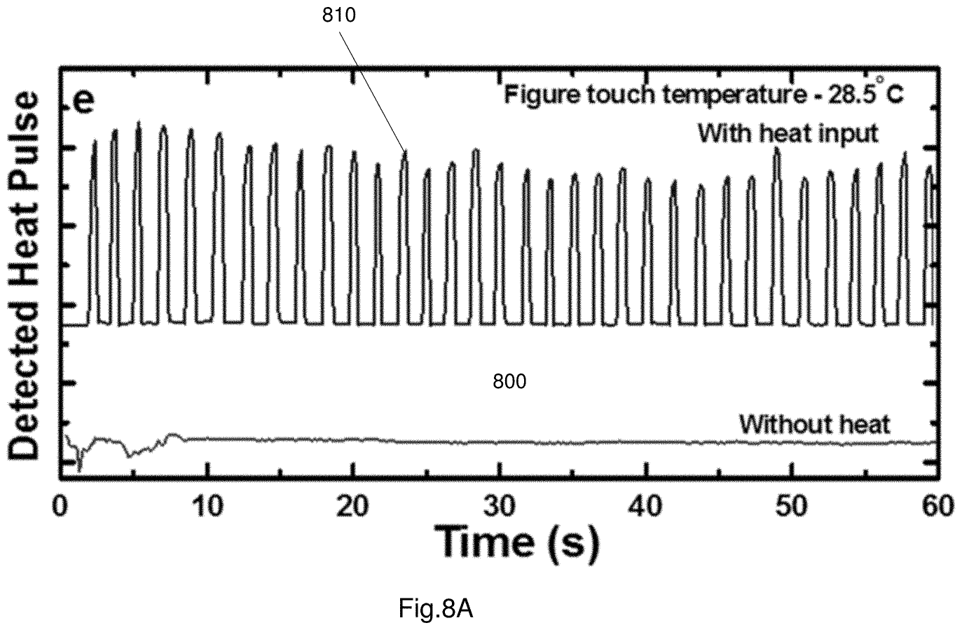

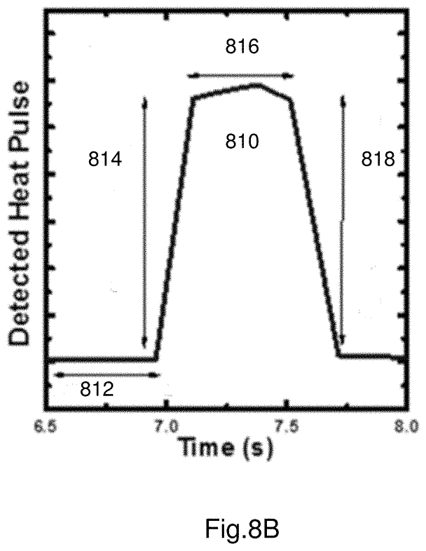

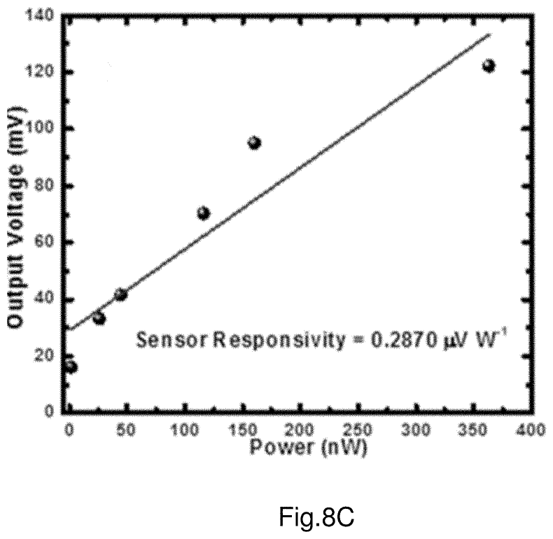

FIG. 8A shows a plot 800 of electrical pulses detected in response to a series of touches detected on the thermoelectric device i.e. touch sensor 700. The plot may be generated on a scope during testing of the touch sensor 700. FIG. 8A illustrates a plurality of pulses 810 which correspond to multiple detected touches. As seen in FIG. 8A each pulse represents a unique detected touch. Each pulse is a current pulse that is detected by the sensor i.e. each pulse is generated representing a detected touch. A unique touch represents the sensor 700 being touched and the finger being removed. Each current pulse is generated due to the body heat from the finger and due to a temperature difference created across the sensor by the finger touch. When the finger is removed the current drops to zero. FIG. 8A shows detected finger touches over 60 seconds. The rise and fall time of each electrical pulse is 150 ms and 200 ms respectively.

FIG. 8B shows a plot of a single electrical pulse 810 i.e. a current pulse from the plot 800 of FIG. 8A. The current signal has a 0 current or low current region 812 which represents a non-contact time. When a finger contact is detected a voltage is induced and current flows through the thermoelectric modules. The pulse comprises a heating cycle 814 i.e. a period of rise time of the current signal. The time the pulse remains high indicates the contact time 816 between the sensor and the finger. Once the finger is lifted off the sensor 700 i.e. no contact or no heat the current is dissipated through a dissipation cycle 818.

The thermoelectric module 710 comprises a large seebeck coefficient. The p type semiconductor elements 712 and the n type semiconductor elements 714 comprise low thermal conductivity. The large seebeck constant and the low thermal conductivity results in a sharp rise and fall time of the current signal e.g. a rise time of 150ms and a fall time of 200ms. The sensor 700 functions as an efficient touch sensor having a high responsivity. FIG. 8C illustrates a graph of the sensor responsivity. In one example form the thermoelectric device 700 i.e. a sensor 700 comprise a sensor responsivity of about 0.2870 μV W⁻¹. The sensor can be constructed to have a desired sensor responsivity depending on the thickness of the p type and n type semiconductor elements 712, 714. The sensing junction i.e. the region of overlap between the p type semiconductor element and the n type semiconductor element can be as required.

The sensor 700 as described herein can be used for fast switching applications with high sensitivity. The sensor 700 construction provides a sensor that has faster switching and higher sensitivity as compared to resistive or capacitive sensors. For example, the sensor 700 can be used for touch heat mapping or imaging applications. Alternatively, the sensor could be used as a touch sensor in other suitable applications. The sensor 700 as described is a thermal touch sensor. The sensor 700 is a standalone sensor without any externally applied voltage. The thermoelectric device 700 (i.e. sensor 700) as described is advantageous because it does not require an external power source or an externally applied voltage. The thermoelectric device 700 (i.e. sensor 700) is also advantageous because the sensor has a high sensitivity value.

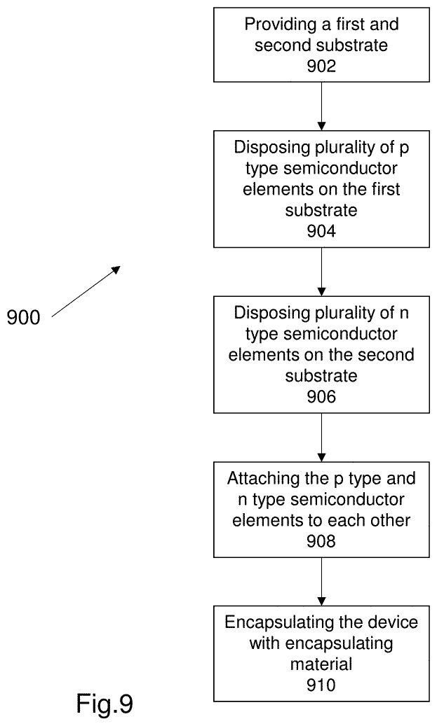

The thermoelectric device 700 (i.e. sensor 700) can be formed by a similar process as the method 300. FIG. 9 illustrates a method 900 of forming a thermoelectric sensor 700 (i.e. thermoelectric device 700). The method commences at step 902. Step 902 comprises providing a first flexible substrate and a second flexible substrate. The substrates are preferably cleaned prior to step 902 by a suitable cleaning process. Step 904 comprises depositing a p type semiconductor element on the first substrate. The p type semiconductor element is deposited by a suitable process e.g. by thermal evaporation. The p type semiconductor element is formed as a thin film. Step 906 comprises depositing a n type semiconductor element on the second substrate. The n type semiconductor element may be deposited by a suitable process e.g. a thermal evaporation. The n type semiconductor element is formed as a thin film on the second substrate. Step 908 comprises attaching the p type and n type semiconductor element in a manner such that a portion of the p type element overlaps the n type element. Step 910 comprises depositing or forming an electrode on the first substrate and an electrode on the second substrate. Optionally the method can comprise step 910 that comprises encapsulating the sensor 700 by a thin encapsulation layer.

The thermoelectric device 100, 200, 700 as described are advantageous because they all provide a self contained device without requiring an external power source. Further the devices are formed of a flexible material that allows the device to be mounted on a limb or about other elements e.g. pipes etc.

The features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

The description of any of these alternative embodiments or configurations is considered exemplary. Any of the alternative embodiments and features in the alternative embodiments can be used in combination with each other or with the embodiments described with respect to the figures.

With reference to FIG. 7, the thermoelectric device may be interchangeably referred to as a sensor or a thermoelectric sensor.

With reference to FIGS. 1A, 1B, 2A and 2B the thermoelectric device may be interchangeable referred to as a power source or a thermoelectric power source i.e. power supply.

The electrodes described herein function as a positive and negative electrode in the power source (i.e. power supply) or the thermoelectric sensor.

Reference to any prior art in this specification is not, and should not be taken as, an acknowledgement or any form of suggestion that the prior art forms part of the common general knowledge in the field of endeavour in any country in the world.

Although the present disclosure has been described in terms of certain embodiments, other embodiments apparent to those of ordinary skill in the art also are within the scope of this disclosure. Thus, various changes and modifications may be made without departing from the spirit and scope of the disclosure. For instance, various components may be repositioned as desired. Features from any of the described embodiments may be combined with each other and/or an apparatus may comprise one, more, or all of the features of the above described embodiments. Moreover, not all of the features, aspects and advantages are necessarily required to practice the present disclosure. Accordingly, the scope of the present disclosure is intended to be defined only by the claims that follow.

The various configurations or embodiments described are exemplary configurations only. Any one or more features from any of the configurations may be used in combination with any one or more features from any of the other configurations.

1. A thermoelectric device for generating electricity comprising:
a flexible substrate,
at least one n type semiconductor element positioned on the substrate,
at least one p type semiconductor element positioned on the substrate,
the at least one n type semiconductor element and the at least one p type semiconductor element are arranged adjacent or in contact with each other on the flexible substrate,
a first electrode and a second electrode positioned on the flexible substrate,
wherein the at least one n type semiconductor element and the at least one p type semiconductor element defining a conductive path to the first and second electrode for electrons to flow, and;
wherein the thermoelectric device generating an electrical power output in response to heat or a temperature gradient applied to the device.

2. A thermoelectric device in accordance with claim 1, further comprising at least one conductor member positioned on the flexible substrate, the at least one p type semiconductor element and the at least one n type semiconductor element positioned adjacent each other and spaced from each other, and wherein the at least one conductor connecting each adjacent n type semiconductor element with an adjacent p type semiconductor element to define a path to conduct the generated electrical power output.

3. A thermoelectric device in accordance with claim 1, wherein the flexible substrate is bendable and comprises a flexural modulus value such that the flexible substrate can bend or be wrapped around about a limb of a human body while maintaining structural integrity.

4. A thermoelectric device in accordance with claim 1, wherein the flexible substrate comprises Polyimide or Polyethylene Terephthalate (PET), Polycarbonate, Polypropylene, Polyethylene, Polyvinyl chloride(PVC).

5. A thermoelectric device in accordance with claim 1, wherein the first electrode and the second electrode being coupled to either of the semiconductor elements or the conductor member.

6. A thermoelectric device in accordance with claim 1, wherein the n type semiconductor element, the p type semiconductor element generating a flow of electric current in response to heat or temperature gradient applied to the device and the electric current flowing through the conductor member.

7. A thermoelectric device in accordance with claim 1, wherein the p type semiconductor element comprises Tin Telluride (SnTe) or Bismuth Antimony Telluride (Bi_{0.5}Sb_{1.5}Te₃) , and the n type semiconductor element comprises Lead Telluride (PbTe) or Bismuth Telluride(Bi₂Te₃).

8. A thermoelectric device in accordance with claim 1, wherein the n type semiconductor element and the p type semiconductor element are elongate legs, each leg comprises a longitudinal axis that is longer than a transverse axis of the leg.

9. A thermoelectric device in accordance with claim 1, wherein the n type semiconductor leg and the p type semiconductor leg being arranged adjacent and parallel to each other.

10. A thermoelectric device in accordance with claim 1, wherein the conductor member comprises a metal that defines a current path for the current generated the semiconductor elements due to an applied heat or an applied temperature gradient.

11. A thermoelectric device in accordance with claim 1, wherein the flexible substrate comprises a flexible sheet comprising a flexural modulus value such that the flexible substrate can bend about a limb of a human body while maintaining structural integrity.

12. A thermoelectric device in accordance with claim 1, wherein the conductor member comprises aluminium or copper.

13. A thermoelectric device in accordance with claim 12, wherein the conductor member comprises an aluminium or copper foil as output contact.

14. A thermoelectric device in accordance with claim 1, wherein the p type semiconductor element and the n type semiconductor element comprise a thin film having a thickness between 50 nm to 150 nm, and preferably 100 nm.

15. A thermoelectric device in accordance with claim 13, wherein the conductor member comprises a thin foil having a thickness of 25 nm to 75 nm, and preferably 50 nm.

16. A thermoelectric device in accordance with claim 1, wherein the thermoelectric device comprises a plurality of p type semiconductor elements and a plurality of n type semiconductor elements, the semiconductor elements arranged in an alternating layout on the flexible substrate, such that one p type semiconductor element is located adjacent one n type semiconductor element in the alternating arrangement.

17. A thermoelectric device in accordance with claim 16, wherein the thermoelectric device comprises a plurality of conductor members, wherein a p type semiconductor element is coupled to an adjacent n type semiconductor arrangement by a conductor member.

18. A thermoelectric device in accordance with claim 16, wherein each p type and n type semiconductor element is coupled to two conductor members, wherein each end of the semiconductor element is coupled to a separate conductor member.

19. A thermoelectric device in accordance with claim 16, wherein the thermoelectric device comprises N number semiconductor elements (sum of p type semiconductor elements and n type semiconductor elements) and;
comprises between N−1 to N+1 number of conductor, and a pair of electrodes.

20. A thermoelectric device in accordance with claim 16, wherein each of the first electrode and second electrode are located at opposing ends of the flexible substrate with the semiconductor elements are arranged in parallel array on a face of the flexible substrate, wherein the semiconductor elements and conductor members defining a series electrical path for the generated current to flow through.

21. A thermoelectric device in accordance with claim 16, wherein the semiconductor elements and the conductor members are disposed in an in-plane layout on a first face of the flexible substrate, and wherein the first face is opposite to a second face of the flexible substrate to which heat is applied.

22. A thermoelectric device in accordance with claim 1, wherein thermoelectric functions as a wearable thermoelectric generator that is configured to generate a current in response to the device being exposed to body heat or a temperature gradient from body heat, and wherein the wearable thermoelectric generator functions as a wearable power source.

23. A thermoelectric device in accordance with claim 1, wherein the thermoelectric device comprises a first flexible substrate and a second flexible substrate, the first flexible substrate supporting the p type semiconductor element and the second flexible substrate supporting the n type semiconductor element, and wherein the thermoelectric device comprising a sandwich structure of the first flexible substrate, the p type semiconductor element, the n type semiconductor element and the second flexible substrate.

24. A thermoelectric device in accordance with claim 23, wherein the p type semiconductor element is connected to and directly contacts a portion of the n type semiconductor element, the n type semiconductor element and p type semiconductor element being connected at a sensing junction to sense an application heat or an application of a temperature gradient to the device.

25. A thermoelectric device in accordance with claim 23, wherein the first electrode is disposed on the first substrate and the second electrode is disposed on the second substrate.

26. A thermoelectric device in accordance with claim 23, wherein the p type semiconductor element overlaps a portion of the n type semiconductor element in region where the p type semiconductor element contacts and is attached to the n type semiconductor element.

27. A thermoelectric device in accordance with claim 23, wherein the heat applied to the first substrate and/or the second substrate causes a pulse of electrical current to be generated due to an applied heat or a temperature gradient, and wherein the amplitude of the pulse of electrical current being related to the magnitude of the applied heat or applied temperature heat gradient.

28. A thermoelectric device in accordance with claim 23, wherein the thermoelectric is configured to function as a touch sensor that is configured to detect a touch from a user by detecting the heat from the touch and generating a current in response.

29. A thermoelectric device that converts heat to electrical power, the thermoelectric device comprising:
a flexible substrate;
a plurality of thermoelectric modules disposed on the flexible substrate,
a first electrode and a second electrode disposed on the flexible substrate, and;
wherein the plurality of thermoelectric modules electrically coupled to each other and at least one thermoelectric module in electrical communication with the first electrode and at least one thermoelectric module in electrical communication with the second electrode, the plurality of thermoelectric modules defining a conductive path between the first electrode and the second electrode, and;
wherein each thermoelectric module generating an electrical current and voltage when exposed to heat or a temperature gradient.

30. A thermoelectric device in accordance with claim 29, wherein each thermoelectric module generates a voltage when exposed to heat or a temperature gradient.

31. A thermoelectric device in accordance with claim 29, wherein each thermoelectric module comprises a p type semiconductor element and a n type semiconductor positioned adjacent each other and separated from each other, wherein each of the semiconductor elements are disposed on the flexible substrate.

32. A thermoelectric device in accordance with claim 29, wherein the thermoelectric modules are arranged adjacent each other on the flexible substrate such that the semiconductor elements are positioned in an alternating layout, wherein a p type semiconductor element is followed by a n type semiconductor element.

33. A thermoelectric device in accordance with claim 29, wherein the thermoelectric device comprises a plurality of conductor members disposed on the flexible substrate, wherein the conductor members providing intra module connections and inter module connections.

34. A thermoelectric device in accordance with claim 33, wherein the intra module connections comprise a conductor member interconnecting the p type semiconductor element and n type semiconductor element defining the thermoelectric module.

35. A thermoelectric device in accordance with claim 33, wherein the inter module connections comprise a conductor member interconnecting adjacent thermoelectric modules together, wherein a p type semiconductor element of a first thermoelectric module is connected to a n type semiconductor element of a second thermoelectric module adjacent the first thermoelectric module.

36. A thermoelectric device in accordance with claim 29, wherein each p type semiconductor element and the n type semiconductor element are coupled to each other by a conductor member.

37. A thermoelectric device in accordance with claim 29, wherein plurality of thermoelectric modules and the conductor members are positioned on the flexible substrate to form an undulating pattern of p type semiconductor elements, n type semiconductor elements and conductor members.

38. A thermoelectric device in accordance with claim 29, wherein the thermoelectric modules are electrically coupled to each other via the conductor members, the conductor members defining an electrical path for the generated electrical current to travel to at least one of the electrodes.

39. A thermoelectric device in accordance with claim 38, wherein the thermoelectric modules are electrically coupled to each other in series connection or a parallel connection.

40. A thermoelectric device in accordance with claim 29, wherein the thermoelectric device comprises four thermoelectric modules and a plurality of conductor members, the conductor members connecting adjacent thermoelectric modules to each other and conductor members interconnecting the semiconductor elements of each thermoelectric module to each other and the thermoelectric modules and conductor elements are arranged in a series electrical connection with each other.

41. A thermoelectric device in accordance with claim 29, wherein the flexible substrate is bendable and comprises a flexural modulus value such that the flexible substrate can bend or be wrapped around about a limb of a human body while maintaining structural integrity.

42. A thermoelectric device in accordance with claim 29, wherein the flexible substrate comprises Polyimide or Polyethylene Terephthalate (PET), Polycarbonate, Polypropylene, Polyethylene, Polyvinyl chloride(PVC).

43. A thermoelectric device in accordance with claim 31, wherein the n type semiconductor element, the p type semiconductor element generating a flow of electric current in response to heat or temperature gradient applied to the device and the electric current flowing through the conductor member.

44. A thermoelectric device in accordance with claim 31, wherein the p type semiconductor element comprises Tin Telluride (SnTe) or Bismuth Antimony Telluride (Bi_{0.5}Sb_{1.5}Te₃) , and the n type semiconductor element comprises Lead Telluride (PbTe) or Bismuth Telluride(Bi₂Te₃).

45. A thermoelectric device in accordance with claim 31, wherein the thermoelectric device comprises three rows of thermoelectric modules and conductor members disposed on the substrate and each row comprising four thermoelectric modules coupled to each other by conductor members.

46. A thermoelectric device in accordance with claim 29, wherein the thermoelectric device as described functions as a flexible power source that converts residual heat or waste heat to electrical power or current and voltage.

47. A thermoelectric device in accordance with claim 29, wherein the thermoelectric device as described functions as a wearable power source that converts body heat to electrical power or current and voltage.
